(19) United States
(12) Patent Application Publication
(10) Pub. No.: US 2026/0059692 A1
(43) Pub. Date: Feb. 26, 2026

(54) WIRELESS CHARGER FOR A VEHICLE

(71) Applicants: HYUNDAI MOTOR COMPANY, Seoul (KR); KIA CORPORATION, Seoul (KR); SL Corporation, Daegu (KR)

(72) Inventors: Dae Joong Kim, Hwaseong si (KR); Jung Hyun Kim, Gyeongsan si (KR); Young Bae Ji, Gyeongsan si (KR)

(73) Assignees: HYUNDAI MOTOR COMPANY, Seoul (KR); KIA CORPORATION, Seoul (KR); SL Corporation, Daegu (KR)

(21) Appl. No.: 18/971,973

(22) Filed: Dec. 6, 2024

(30) Foreign Application Priority Data
Aug. 26, 2024 (KR) 10 2024 0114422

(51) Int. Cl. H05K 7/20; B60R 16/03; H02J 50/00; H02J 50/10

(52) U.S. Cl. CPC H05K 7/20145; B60R 16/03; H02J 50/005; H02J 50/10

(57) ABSTRACT

A wireless charger for a vehicle includes a housing, a blower fan disposed in a lower portion of the housing and configured to draw in air from below, a printed circuit board disposed in the housing, a coil bracket disposed above the printed circuit board, and a coil seated on an upper surface of the coil bracket and configured to generate a magnetic field when a current flows. In particular, a cooling channel may be formed in the upper surface of the coil bracket, and air may pass through the cooling channel and cool a lower portion of the coil while the coil is seated.

### CROSS-REFERENCE TO RELATED APPLICATION

This application claims priority to and the benefit of Korean Patent Application No. 10-2024-0114422, filed on Aug. 26, 2024, the entire contents of which are incorporated herein by reference.

### BACKGROUND

### 1. Field

The present disclosure relates to a wireless charger for a vehicle, and more specifically, to a wireless charger for a vehicle to improve its cooling efficiency.

### 2. Discussion of Related Art

Charging methods for electronic devices are divided into contact type charging methods and non-contact type charging methods. The contact type charging method is a method of brining an electrode connected to a battery of an electronic device into direct close contact with an electrode of an electricity supply to charge the battery. Because a structure for the contact type charging method is simple, the contact type charging method is generally used in various fields. However, there is inconvenience of physically connecting the electrode of the electronic device and the electricity supply, such as a connector connection.

In order to solve such inconvenience of such contact type charging methods, the non-contact type charging methods are proposed. The non-contact type charging method, i.e., a wireless charging method, is a method of performing charging using electromagnetic induction. This wireless charging method uses a charger (e.g., wireless power transmission device) including a primary coil (transmission coil), and an electronic device (wireless power receiving device) including a secondary coil (reception coil) such that a current generated through an electromagnetic induction method between the primary coil and the secondary coil is converted into energy for charging a battery.

Components such as a blower fan for introducing air into a wireless charger for a vehicle, a coil, a coil seating part on which the coil is seated are installed in the wireless charger for a vehicle to which a wireless charging method is applied. A wireless charger adopts a structure for cooling heat generated in the wireless charger using an air flow suctioned from the outside.

However, the conventional wireless charger had an issue with insufficient cooling of a printed circuit board (PCB) because it used a blowing guide structure to direct the air from a blower fan, focusing cooling only on a specific portion, such as a coil, which is intensively cooled by the air. In addition, since an air inlet port through which the blower fan may suction the air is limited to a lower side, problems that cooling effect for a lower end portion of the PCB is reduced and a noise due to the suctioned air is generated. Due to these structural limitations, there are problems that a type of applicable blower fan is limited and costs increase due to addition of unnecessary parts.

### SUMMARY

The present disclosure provides a wireless charger for a vehicle. The wireless charger may include: a cooling channel formed on a seating part on which a coil is seated to flow air, and auxiliary cooling parts formed at both sides of an coil bracket such that the air comes into direct contact with the coil to intensively cool the heated coil while the air flows through the cooling channel and the air discharged to the auxiliary cooling parts cools a printed circuit board.

In an embodiment of the present disclosure, a wireless charger for a vehicle includes a housing that has an air guide part at a side surface to enhance design simplicity and reduce costs by reducing the number of components.

Objectives of the present disclosure are not limited to the above-described objectives, and the other objectives which are not described above should be clearly understood to those having ordinary skill in the art from the following descriptions.

According to an aspect of the present disclosure, there is provided a wireless charger for a vehicle. The wireless charger includes: a housing, a blower fan which is disposed in a lower portion of the housing and suctions air from below, a printed circuit board disposed in the housing, a coil bracket disposed above the printed circuit board, and a coil. The coil is seated on an upper surface of the coil bracket and generates a magnetic field when a current flows. In particular, a cooling channel is formed in the upper surface of the coil bracket, and air passes through the cooling channel and cools a lower portion of the coil.

The coil bracket may include a seating part in which the cooling channel is formed, The coil is seated on the seating part, and the seating part protrudes upward.

The seating part may be formed in a disk shape corresponding to the coil.

The cooling channel may be provided as a plurality of cooling channels formed in the seating part in an air flow direction. The plurality of cooling channels may be formed such that a width of them increases from both sides toward a central portion thereof.

The cooling channel may be formed to a full height of the seating part.

An inflow guide part for guiding a flow of the air introduced from below may be formed at an air inflow entrance side of the coil bracket.

The inflow guide part may be formed to be inclined upward in an air flow direction.

Auxiliary cooling parts through which air flows downward may be formed to be open at both sides of the coil bracket, and the air flowing through the auxiliary cooling parts may cool the printed circuit board.

A guide wall for guiding air suctioned by the blower fan toward a side surface of the housing may be provided in the housing, and air flowing along the guide wall may be introduced to the coil bracket.

The housing may include: a base part on which the blower fan, the printed circuit board, and the coil bracket are installed, and a cover part coupled to the base part to cover an upper portion of the base part.

The cover part may protrude outward further than a side surface of the base part to cover a side portion of the base part such that air is guided between the side surface of the base part and a side surface of the cover part.

A charging pad may be coupled to an upper surface of the housing.

According to another aspect of the present disclosure, there is provided a wireless charger for a vehicle. The wireless charger includes: a housing, a blower fan disposed in a lower portion of the housing and configured to drawn in air from below, a printed circuit board disposed in the housing, a coil bracket disposed above the printed circuit board, and a coil seated on an upper surface of the coil bracket and configured to generate a magnetic field when a current flows. In one embodiment, auxiliary cooling parts through which the air flows downward are formed to be open at both sides of the coil bracket, and the air flowing through the auxiliary cooling parts cools the printed circuit board.

An inflow guide part for guiding a flow of the air introduced from below may be formed at an air inflow entrance side of the coil bracket.

The inflow guide part may be formed to be inclined upward in an air flow direction.

### BRIEF DESCRIPTION OF THE DRAWINGS

The above and other objects, features and advantages of the present disclosure should become more apparent to those of ordinary skill in the art by describing some embodiments thereof in detail with reference to the accompanying drawings, in which:

FIG. 1 is an exploded perspective view illustrating a wireless charger for a vehicle according to one embodiment of the present disclosure;

FIG. 2 is a perspective view illustrating the wireless charger for a vehicle according to one embodiment of the present disclosure;

FIG. 3 is a perspective view illustrating a housing of the wireless charger for a vehicle according to one embodiment of the present disclosure;

FIG. 4 is a view illustrating an air guide part of the housing according to one embodiment of the present disclosure;

FIG. 5 is a perspective view illustrating a coil bracket of the wireless charger for a vehicle according to one embodiment of the present disclosure;

FIG. 6 is a view illustrating an air flow direction in the coil bracket according to one embodiment of the present disclosure;

FIG. 7 is a view illustrating a printed circuit board which is being cooled by an air flow in the coil bracket according to one embodiment of the present disclosure;

FIG. 8 is a view illustrating an air flow direction in a coil bracket of a wireless charger for a vehicle according to another embodiment of the present disclosure; and

FIG. 9 is a cross-sectional view illustrating an internal air flow of the wireless charger for a vehicle according to one embodiment of the present disclosure.

### DETAILED DESCRIPTION

Since the present disclosure may be variously modified and have several embodiments, specific embodiments are illustrated in the accompanying drawings and described in detail. However, this is not intended to limit the present disclosure to the specific embodiments, and it should be appreciated that all changes, equivalents, and substitutes falling within the spirit and technical scope of the present disclosure are encompassed in the present disclosure. In the description of the embodiments, certain detailed descriptions of the related art have been omitted when it is deemed that they may unnecessarily obscure the gist of the inventive concept.

Terms such as “first” and “second” may be used to describe various components, but the components are not limited by the above terms. These terms are used only to distinguish one component from another.

Terms used herein are only for the purpose of describing particular embodiments and are not intended to limit the present disclosure. Singular forms are intended to include the plural forms, unless the context clearly indicates otherwise. In the present specification, it should be understood that the terms “comprise,” “comprising,” “include,” and/or “including” used herein specify the presence of stated features, numbers, steps, operations, elements, components, and/or combinations thereof but do not preclude the presence or addition of one or more other features, numbers, steps, operations, elements, components, and/or combinations thereof.

In addition, throughout the specification, when components are “connected,” this may not only mean that two or more components are directly connected, but this may also mean that two or more components are indirectly connected through other components or are physically connected and also electrically connected, or are one thing even referred to as different names according to positions or functions thereof. When a component, device, element, or the like of the present disclosure is described as having a purpose or performing an operation, function, or the like, the component, device, or element should be considered herein as being “configured to” meet that purpose or to perform that operation or function.

In addition, when a first component is described as being formed or disposed “on” or “under” a second component, such a description includes both a case in which the two components are formed or disposed in direct contact with each other and a case in which one or more other components are interposed between the two components. In addition, when the first component is described as being formed “on or under” the second component, such a description may include a case in which the first component is formed at an upper side or a lower side with respect to the second component.

Hereinafter, embodiments of a wireless charger for a vehicle are described in detail with reference to the accompanying drawings, and when the embodiments are described with reference to the accompanying drawings, components which are the same or correspond to each other are denoted by the same reference numerals, and redundant description thereof is omitted.

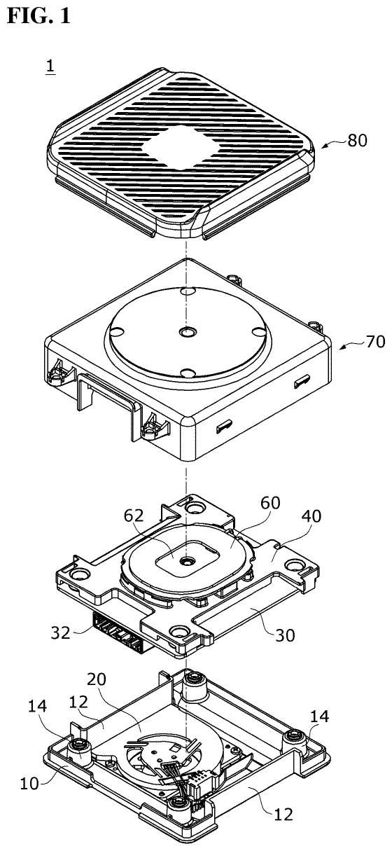

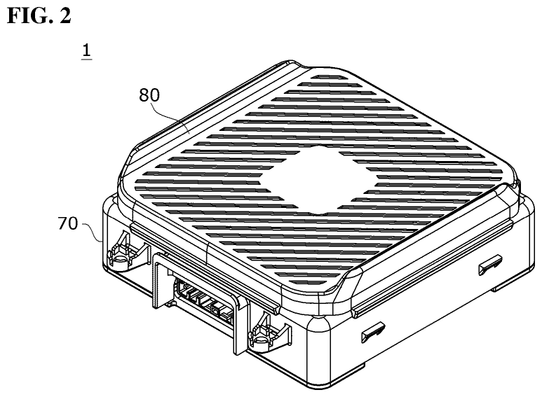

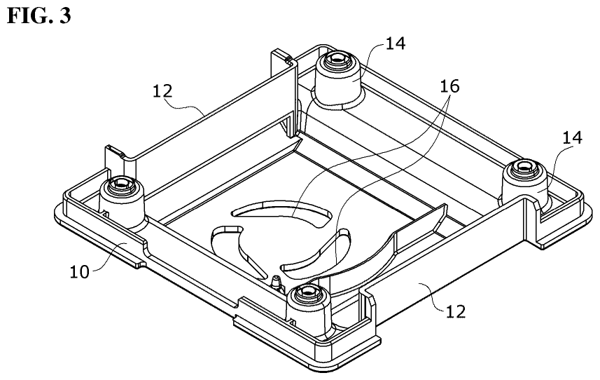

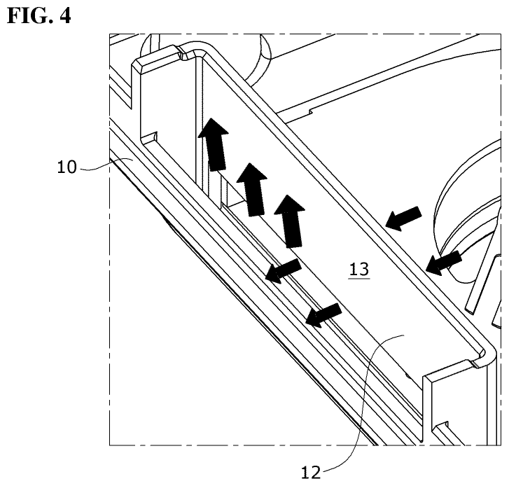

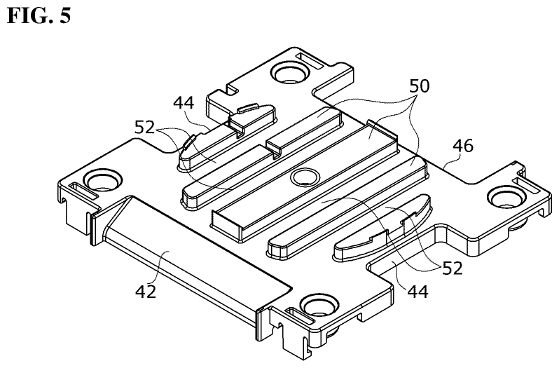

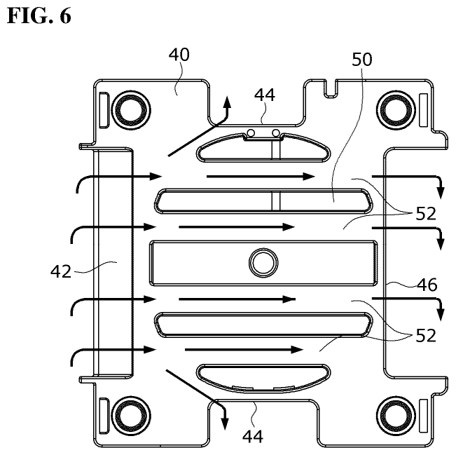

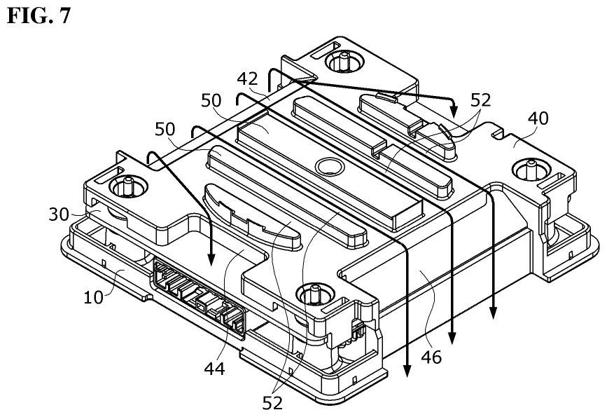

FIG. 1 is an exploded perspective view illustrating a wireless charger for a vehicle according to one embodiment of the present disclosure, and FIG. 2 is a perspective view illustrating the wireless charger for a vehicle according to one embodiment of the present disclosure. FIG. 3 is a perspective view illustrating a housing of the wireless charger for a vehicle according to one embodiment of the present disclosure, and FIG. 4 is a view illustrating an air guide part of the housing. FIG. 5 is a perspective view illustrating a coil bracket of the wireless charger for a vehicle according to one embodiment of the present disclosure, and FIG. 6 is a view illustrating an air flow direction in the coil bracket. FIG. 7 is a view illustrating a printed circuit board that is being cooled by an air flow in the coil bracket.

According to one embodiment of the present disclosure, the wireless charger for a vehicle includes a housing 1, a blower fan 20 which is disposed in a lower portion of the housing 1 and suctions air from below, a printed circuit board 30 disposed in the housing 1, a coil bracket 40 disposed above the printed circuit board 30, and a coil 60 which is seated on an upper surface of the coil bracket 40 and generates a magnetic field when a current flows. In one embodiment, a cooling channel 52 is formed in the upper surface of the coil bracket 40, and air may cool a lower portion of the coil 60 while passing through the cooling channel 52 in a state in which the coil 60 is seated.

The housing 1 may be a part forming an exterior of the wireless charger for a vehicle and may be formed in a rectangular hexahedron shape having a predetermined volume. Referring to FIG. 6, the housing 1 does not form an entire exterior of the wireless charger and may include a base part 10 and a cover part 70 coupled to the base part 10. The blower fan 20, the printed circuit board 30, and the coil bracket 40 are sequentially installed on the base part 10, and the cover part 70 coupled to the base part 10 covers an open upper portion of the base part 10. However, this is only to propose one embodiment, and the entire housing 1 may be formed integrally.

Referring to FIGS. 3 and 4, a guide wall 12 for guiding the air suctioned by the blower fan 20 toward the side surface of the housing 1 is provided in the housing 1. Accordingly, the air flowing along the guide wall 12 may be introduced to the coil bracket 40 along an air guide part 13 formed outside the guide wall 12.

As described above, a portion of a sidewall of the housing 1 may be recessed inward to form the guide wall 12. In other words, as a central portion of the sidewall of the housing 1 is mainly formed to be recessed inward to a predetermined length, the air guide part 13 may be naturally formed between the guide wall 12 and an inner surface of the cover part 70. Then, the air suctioned by the blower fan 20 may be introduced to the coil bracket 40 disposed above the blower fan 20 through the air guide part 13 formed along the side surface of the housing 1.

In one embodiment, the guide wall 12 is formed to be recessed inward, and the air guide part 13 is formed between the guide wall 12 and the cover part 70, but the present disclosure is not limited thereto. For example, the guide wall 12 may be disposed inside and spaced apart from the sidewall of the housing 1, and the air guide part 13 may be formed between the sidewall of the housing 1 and the guide wall 12 to guide an air flow. In another embodiment, a sidewall of the cover part 70 may be formed to protrude outward, and the air guide part 13 may be formed between the sidewall of the cover part 70 and the sidewall of the housing 1 to guide air. In other words, any structure capable of guiding air suctioned through a lower surface of the housing 1 to the coil bracket 40 may be adopted in the housing 1.

As described above, as the air guide part 13 is formed along the sidewall of the housing 1 by changing a structure of the housing 1, ease of design can be improved, and costs can be reduced by reducing the number of components.

A fastening boss 14 is provided in each corner of the housing 1. The fastening boss 14 is a part to which a screw is fastened from the outside of the housing 1, and the screw passing through the fastening boss 14 is fastened to the cover part 70 to couple the housing 1 and the cover part 70.

In addition, an air hole 16 is formed to pass through the lower surface of the housing 1. The air hole 16 is a hole through which air suctioned into the housing 1 passes, and the air hole 16 may be provided as a plurality of air holes 16 in the lower surface of the housing 1 in a rotation direction of the blower fan 20.

The blower fan 20 is installed at a lower side in the housing 1 and may draw in air from the outside to cool an inner portion of the housing 1. The blower fan 20 may be driven by power applied through a connector 32 of the printed circuit board 30.

The printed circuit board 30 may be installed above the blower fan 20. The printed circuit board 30 serves to control various components installed in the housing 1 using the power applied through the connector 32. The connector 32 is soldered to a lower end of the printed circuit board 30 to serve to supply power to the wireless charger.

The coil bracket 40 may be disposed above the printed circuit board 30. The coil bracket 40 is a bracket on which the coil 60 is seated on the upper surface thereof and serves to functions for mounting the coil 60 and also cooling the coil 60 using an air flow.

An inflow guide part 42 for guiding a flow of air introduced from below is formed at an air inflow entrance side or air inflow front end side of the coil bracket 40 to guide an air flow. The inflow guide part 42 is formed to be inclined upward in an air flow direction so that air is more easily introduced to the coil bracket 40. The inflow guide part 42 may be formed in a plate shape at the air inflow entrance side of the coil bracket 40. In the present drawings, the inflow guide part 42 is formed to be inclined upward but is not limited thereto, and may be formed in a horizontal direction. In addition, the inflow guide part 42 may be formed in a shape of a plurality of tips to guide inflow of air instead of a single plate shape.

In another embodiment of the present disclosure, a wireless charger for a vehicle may include a housing 1, a blower fan 20 which is disposed in a lower portion of the housing 1 and draws in air from below, a printed circuit board 30 disposed in the housing 1, a coil bracket 40 disposed above the printed circuit board 30, and a coil 60 which is seated on an upper surface of the coil bracket 40 and generates a magnetic field when a current flows. In an embodiment, auxiliary cooling parts 44 may be formed to be open at both sides of the coil bracket 40, and air flows downward through the auxiliary cooling parts 44. The auxiliary cooling parts 44 are parts formed to effectively cool the printed circuit board 30 disposed therebelow by allowing the air introduced to the coil bracket 40 to flow downward.

As an example, portions of both sides of the coil bracket 40 may be cut to form the auxiliary cooling parts 44. As an example, the auxiliary cooling parts 44 may be implemented using holes or slots, through which air is discharged, at both sides of the coil bracket 40. In addition, the auxiliary cooling part 44 may be formed in a plate shape like the inflow guide part 42 to be inclined downward to guide air to flow downward. The important fact is that some of air introduced to the coil bracket 40 flows downward while flowing to directly cool the printed circuit board 30.

An outlet port 46 may be formed to be open at an air inflow exit side or air inflow rear end side of the coil bracket 40. The outlet port 46 may be a port through which air passing through the coil bracket 40 is discharged, and a portion of a rear end side of the coil bracket 40 may be cut to form the outlet port 46. In addition, although not specifically illustrated in the present drawing, a component such as an inflow guide part 42 may be formed such that the discharged air is smoothly discharged to the outside of the housing 1. In this case, a guide for discharging may be formed to be inclined downward.

Seating parts 50 on which the coil 60 is seated may be formed to protrude from the upper surface of the coil bracket 40. The seating part 50 is a part for seating of the coil 60 and serves to form an air path for cooling the coil 60 and the printed circuit board 30. As an example, the seating part 50 may be formed in a disk shape corresponding to the shape of the coil 60. The coil 60 allows wireless charging in an electromagnetic induction manner with a coil of an electronic device. A ferrite 62 serves to provide a seating surface for the coil 60 and minimizes energy loss due to electromagnetic waves to improve energy efficiency.

The seating part 50 may have a predetermined thickness, and a cooling channel 52 for an air flow may be formed in the seating part 50. First, referring to FIGS. 5 and 6, the cooling channel 52 may be provided as a plurality of cooling channels 52 in the seating part 50 in an air flow direction. As an example, the cooling channel 52 may be provided as the plurality of cooling channels 52, which are parallel in the air flow direction, in the seating part 50. Some portion of the seating part 50 may be removed in the air flow direction to form the cooling channel 52, or a portion of the seating part 50 excluding a portion corresponding to the cooling channel 52 may protrude to form the cooling channel 52.

In the present drawings, the cooling channel 52 is illustrated to be formed between the seating parts 50, of which portions of a total height are removed, but is not limited thereto, and may be formed in the air flow direction to pass through a portion of the seating part 50 in the height direction. However, as in the present drawings, when the cooling channel 52 is formed in the size of the total height of the seating part 50, since an air flow may be easier and come into direct contact with a lower surface of the coil 60, it is more advantageous for cooling the coil 60.

As an example, the cooling channel 52 may be provided as the plurality of cooling channels 52 in the seating part 50 in the air flow direction. As an example, one cooling channel 52 may be formed in a central portion of the seating part 50 in the air flow direction.

As described above, when the cooling channel 52 is formed in the seating part 50 and air passes through the cooling channel 52, the lower surface of the coil 60, of which heat greatly affects delay of charging, may be directly cooled. That is, since the air may directly come into contact with and cool the heated coil 60 while flowing through the plurality of cooling channels 52, the coil 60 can be intensively cooled.

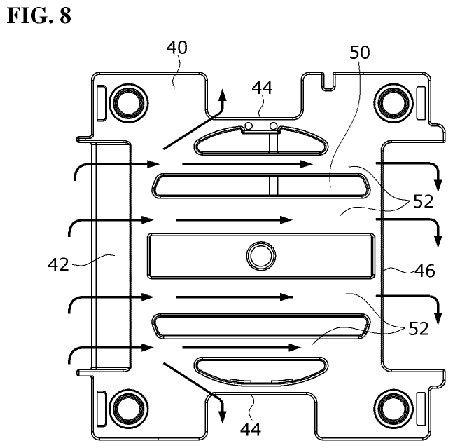

FIG. 8 is a view illustrating the air flow direction in the coil bracket of the wireless charger for a vehicle according to another embodiment of the present disclosure.

Referring to the drawing, in the present embodiment, the cooling channels 52 may be formed such that widths increase toward the central portion from both sides thereof. In other words, as the widths of the cooling channels 52 disposed at the central portion among the plurality of cooling channels 52 are increased, a surface in contact with the coil 60 is maximized so as to intensively cool the coil 60.

For example, when a total of four cooling channels 52 are formed in the air flow direction, two cooling channels 52 disposed at the central portion may be formed to be relatively great, and two cooling channels 52 disposed at both side portions may be formed to be relatively small.

Referring to FIGS. 1 and 2 again, a charging pad 80 is coupled to an upper surface of a cover part 70. The charging pad 80 is a pad on which an electronic device, for example, a smartphone is seated for charging, and of which a surface is formed of a frictional material to prevent the smartphone from sliding when a vehicle suddenly brakes or starts.

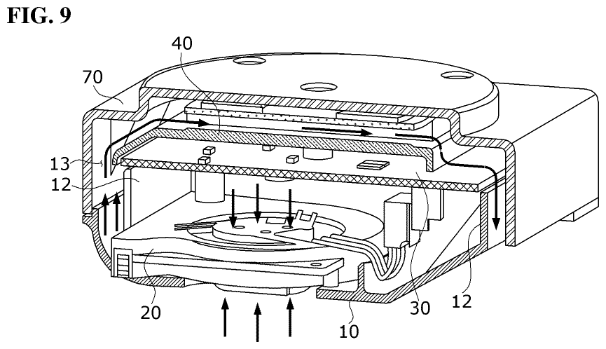

FIG. 9 is a cross-sectional view illustrating an internal air flow of the wireless charger for a vehicle according to one embodiment of the present disclosure.

Referring to the drawing, when power is applied to the wireless charger through the connector 32, the wireless charger receives a driving signal from the printed circuit board 30 and drives the blower fan 20. When the blower fan 20 is driven, air may be suctioned through the air hole 16 formed in the housing 1.

As described above, the suctioned air is guided to the air guide part 13 formed along an inner side surface of the housing 1 without being introduced to the printed circuit board 30 and the coil 60. The air flowing upward through the air guide part 13 may be turned in a horizontal direction and may be introduced to the coil bracket 40.

The air introduced to the inflow guide part 42 of the coil bracket 40 passes through the cooling channel 52 and comes into direct contact with a lower surface of the coil 60 to cool the coil 60. At the same time, some of the introduced air flows downward through the auxiliary cooling parts 44 formed at both sides of the coil bracket 40 and cools the printed circuit board 30 disposed under the coil bracket 40. As described above, the present embodiment has an advantage of guiding a flow direction of the air, which is introduced to the coil bracket 40, to simultaneously cool the coil 60 and the printed circuit board 30.

The air passing through the cooling channel 52 and heated through heat exchange may be discharged to the outside through the outlet port 46.

According to one embodiment of the present disclosure, since a cooling channel through which air flows is formed on a seating part on which a coil is seated and auxiliary cooling parts are formed at both sides of a coil bracket, the air can come into direct contact with the coil to intensively cool the heated coil while the air flows through the cooling channel, and the air discharged to the auxiliary cooling parts can cool a printed circuit board. As a result, wireless charging performance can be improved by improving a cooling effect for components.

In addition, according to one embodiment of the present disclosure, since a structure of a housing is changed to have an air guide part at a side surface, ease of design can be improved and costs can be reduced by reducing the number of components.

While the present disclosure has been described above with reference to specific embodiments of the present disclosure, it may be understood by those having ordinary skill in the art that various modifications and changes of the present disclosure may be made within a range not departing from the spirit and scope of the present disclosure defined by the appended claims.

What is claimed is:

1. A wireless charger for a vehicle, comprising:
a housing;
a blower fan disposed in a lower portion of the housing and configured to suction air from below;
a printed circuit board disposed in the housing;
a coil bracket disposed above the printed circuit board; and
a coil seated on an upper surface of the coil bracket and configured to generate a magnetic field when a current flows,
wherein a cooling channel is formed in the upper surface of the coil bracket, and air passes through the cooling channel and cools a lower portion of the coil.

2. The wireless charger of claim 1, wherein the coil bracket includes a seating part in which the cooling channel is formed, wherein the coil is seated on the seating part, and the seating part protrudes upward.

3. The wireless charger of claim 2, wherein the seating part is formed in a disk shape corresponding to the coil.

4. The wireless charger of claim 2, wherein the cooling channel is provided as a plurality of cooling channels formed in the seating part in an air flow direction.

5. The wireless charger of claim 4, wherein the plurality of cooling channels are formed such that a width thereof increases from both sides toward a central portion thereof.

6. The wireless charger of claim 2, wherein the cooling channel is formed to a full height of the seating part.

7. The wireless charger of claim 1, wherein an inflow guide part for guiding a flow of the air introduced from below is formed at an air inflow entrance side of the coil bracket.

8. The wireless charger of claim 7, wherein the inflow guide part is formed to be inclined upward in an air flow direction.

9. The wireless charger of claim 1, wherein:
auxiliary cooling parts through which air flows downward are formed to be open at both sides of the coil bracket; and
the air flowing through the auxiliary cooling parts cools the printed circuit board.

10. The wireless charger of claim 1, wherein:
a guide wall guiding the air suctioned by the blower fan toward a side surface of the housing is provided in the housing; and
air flowing along the guide wall is introduced to the coil bracket.

11. The wireless charger of claim 1, wherein the housing includes:
a base part on which the blower fan, the printed circuit board, and the coil bracket are installed; and
a cover part coupled to the base part and configured to cover an upper portion of the base part.

12. The wireless charger of claim 11, wherein the cover part protrudes outward further than a side surface of the base part to cover a side portion of the base part such that air is guided between the side surface of the base part and a side surface of the cover part.

13. The wireless charger of claim 1, wherein a charging pad is coupled to an upper surface of the housing.

14. A wireless charger for a vehicle, comprising:
a housing;
a blower fan disposed in a lower portion of the housing and configured to draw in air from below;
a printed circuit board disposed in the housing;
a coil bracket disposed above the printed circuit board; and
a coil seated on an upper surface of the coil bracket and configured to generate a magnetic field when a current flows,
wherein auxiliary cooling parts through which air flows downward are formed to be open at both sides of the coil bracket, and the air flowing through the auxiliary cooling parts cools the printed circuit board.

15. The wireless charger of claim 14, wherein an inflow guide part for guiding a flow of the air introduced from below is formed at an air inflow entrance side of the coil bracket.

16. The wireless charger of claim 15, wherein the inflow guide part is formed to be inclined upward in an air flow direction.
